(19) United States
(12) Patent Application Publication
(10) Pub. No.: US 2011/0203654 A1
(43) Pub. Date: Aug. 25, 2011

(54) ORGANIC THIN-FILM SOLAR CELL AND METHOD FOR MANUFACTURE THEREOF

(76) Inventors: Takeshi Kihara, Tokyo-to (JP); Hiroyuki Suzuki, Tokyo-to (JP)

(21) Appl. No.: 12/998,510

(22) PCT Filed: Dec. 4, 2009
(86) PCT No.: PCT/JP2009/070415

§ 371 Date: Apr. 28, 2011

(30) Foreign Application Priority Data
Dec. 4, 2008 (JP) 2008310094
Jun. 22, 2009 (JP) 2009147904

(51) Int. Cl. H01L 31/0224; H01L 51/48; H01L 51/44

(52) U.S. Cl. 136/256; 438/82; 257/E51.012

(57) ABSTRACT

A main object of the present invention is to provide an organic thin-film solar cell in which a short circuit hardly occurs between the electrodes and which has high photoelectric conversion efficiency even when formed to have a large area. To achieve the object, provided is an organic thin-film solar cell comprising: a transparent substrate, a mesh electrode and a transparent electrode laminated in any order on the transparent substrate, a photoelectric conversion layer formed on the mesh electrode and the transparent electrode, and a counter electrode formed on the photoelectric conversion layer, characterized in that the mesh electrode has such a thickness that no short circuit occurs between the counter electrode and the mesh electrode and the transparent electrode.

### TECHNICAL FIELD

The invention relates to an organic thin-film solar cell having a mesh electrode.

### BACKGROUND ART

An organic thin-film solar cell, which has an organic thin film that is placed between two different types of electrodes and has an electron-donating function and an electron-accepting function, has the advantage that its manufacturing process is easier than that of an inorganic solar cell such as a silicon solar cell and can be formed to have a large area at low cost.

In a solar cell, a transparent electrode is used as a light receiving side electrode. A metal oxide such as ITO is conventionally used for such a transparent electrode, and in particular, ITO is generally used because of its high electrical conductivity and transparency and its high work function.

Unfortunately, an ITO electrode used in an organic thin-film solar cell has a small thickness of about 150 nm and a high sheet resistance of about 20 Ω/square, and therefore has the problem that a generated current is consumed when passing through the ITO electrode so that the power generation efficiency is reduced. This phenomenon becomes more significant as the area of the organic thin-film solar cell increases.

In recent years, there has been a proposal to laminate a metal mesh on a transparent electrode in a silicon solar cell or a dye-sensitized solar cell (see for example Patent Literatures 1 to 3). There has also been a proposal to place, on a part of a transparent electrode, an auxiliary electrode having higher electrical resistance than the transparent electrode in an organic thin-film solar cell (see Patent Literature 4). This can improve the electrical conductivity of the electrode.

### Citation List

Patent Literature 1: Japanese Patent Application Laid-Open (JP-A) No. 2000-243989

Patent Literature 2: JP-A No. 2000-243990

Patent Literature 3: JP-A No. 2008-243425

Patent Literature 4: JP-A No. 2004-158661

### SUMMARY OF INVENTION

### Technical Problem

In an organic thin-film solar cell, therefore, a metal mesh may be laminated on a transparent electrode so that increased power generation efficiency can be attained.

Unfortunately, the metal mesh used in the silicon solar cell or the dye-sensitized solar cell has a thickness of about 2 μm to about 20 μm, which is very thick. In an organic thin-film solar cell, an organic layer such as a photoelectric conversion layer has a thickness of 100 nm to 200 nm, which is very thin. Therefore, if the metal mesh for the silicon solar cell or the dye-sensitized solar cell is directly used in an organic thin-film solar cell, a problem will occur in which a short circuit occurs between the electrodes because the organic layer such as the photoelectric conversion layer is thin.

The invention has been made in view of the above problems, and a main object of the invention is to provide an organic thin-film solar cell in which a short circuit hardly occurs between the electrodes and which has high photoelectric conversion efficiency even when formed to have a large area.

### Solution to Problem

To solve the above problems, the invention provides an organic thin-film solar cell, comprising: a transparent substrate; a mesh electrode and a transparent electrode laminated in any order on the transparent substrate; a photoelectric conversion layer formed on the mesh electrode and the transparent electrode; and a counter electrode formed on the photoelectric conversion layer, wherein the mesh electrode has such a thickness that no short circuit occurs between the counter electrode and the mesh electrode and the transparent electrode.

According to the invention, a laminate of the mesh electrode and the transparent electrode is used as an anode-side electrode. Therefore, even though the sheet resistance of the transparent electrode is relatively high, the sheet resistance of the whole of the anode can be kept at a sufficiently low level, because the mesh electrode can have a sufficiently low resistance. Therefore, even when formed to have a large area, the organic thin-film solar cell of the invention can efficiently collect the generated power and therefore achieve high power generation efficiency. According to the invention, the thickness of the mesh electrode is also such that no short circuit occurs between the counter electrode and the mesh electrode and the transparent electrode, so that a short circuit is prevented between the electrodes.

In the invention, the mesh electrode preferably has the thickness in a range of 200 nm to 300 nm. If the mesh electrode is too thin, the mesh electrode may have too high sheet resistance, and if the mesh electrode is too thick, a short circuit may occur between the electrodes.

In addition, in the invention, the mesh electrode preferably has a hexagonal or parallelogram lattice shape. This is because a current flowing through the mesh electrode can be prevented from being localized.

Furthermore, in the invention, the mesh electrode preferably has an opening ratio in a range of 80% to 98%. If the opening ratio is too low, the amount of light incident on the photoelectric conversion layer may be small, and if the opening ratio is too high, the mesh electrode may have high resistance.

Furthermore, in the invention, the mesh electrode is preferably a metal thin film formed by a vacuum film forming method. The vacuum film forming method such as sputtering can form a metal thin film with uniform thickness and good adhesion on a transparent substrate such as a glass substrate or a PET film.

In addition, in the invention, the mesh electrode and the transparent electrode are preferably laminated in this order on the transparent substrate. When the transparent electrode has a large contact area with a photoelectric conversion layer, a hole extraction layer or the like, good interface bonding is achieved.

Furthermore, in the invention, the transparent electrode and the mesh electrode may be laminated in this order on the transparent substrate.

In addition, the invention provides a method for manufacturing an organic thin-film solar cell, in which the organic thin-film solar cell comprises: a transparent substrate, a mesh electrode and a transparent electrode that are laminated in any order on the transparent substrate, a photoelectric conversion layer formed on the mesh electrode and the transparent electrode, and a counter electrode formed on the photoelectric conversion layer, and the method comprises: a mesh electrode-forming step of forming a metal thin film on the transparent substrate, placing a resist on the metal thin film, and pattering the metal thin film into a mesh structure by a photo-etching method to form the mesh electrode.

According to the invention, the mesh electrode is formed by a photo-etching method. Therefore, even when the metal thin film is relatively thin, a desired patterning can be accomplished. In addition, the mesh electrode can be formed to have a burr-fee edge shape. Therefore, the mesh electrode can be formed to have such a thickness that no short circuit occurs between the electrodes, and the mesh electrode can be formed in such a shape that a short circuit is prevented, which would otherwise be caused by a burr at the edge of the mesh electrode. This makes it possible to obtain an organic thin-film solar cell in which a short circuit hardly occurs between the electrodes. According to the invention, the mesh electrode and the transparent electrode are laminated to form an anode, which makes it possible to manufacture an organic thin-film solar cell that exhibits good power generation efficiency even when it has a large area.

In the above-mentioned invention of the manufacturing method, it is preferable that the mesh electrode has a thickness in a range of 200 nm to 300 nm and the method further comprises after the mesh electrode-forming step: a photoelectric conversion layer-forming step of forming the photoelectric conversion layer by a method capable of controlling a thickness mainly depending on an amount of coating. The method capable of controlling the thickness mainly depending on the amount of coating is suitable for forming a large-area solar cell. When the photoelectric conversion layer is formed by this method, setting the mesh electrode thickness at more than the above range may make it difficult to cover the edge of the mesh electrode so that a short circuit may be more likely to occur between the electrodes. If the thickness of the mesh electrode is more than the above range, the photoelectric conversion layer may be formed with a thickness greater than the desired thickness due to the surface tension, so that it may become hard to extract the electric energy, which is generated in the photoelectric conversion layer, to the uppermost layer. On the other hand, if the mesh electrode is too thin, the mesh electrode may have high sheet resistance.

In addition, in the invention, the metal thin film is preferably patterned into a hexagonal or parallelogram lattice shape in the mesh electrode-forming step. This is because a current flowing through the mesh electrode can be prevented from being localized.

### Advantageous Effects of Invention

According to the invention, the anode-side electrode is a laminate of the mesh electrode and the transparent electrode, and the mesh electrode has the specified thickness. Therefore, the invention brings about the advantage that a short circuit is prevented between the electrodes and high power generation efficiency can be achieved even when the organic thin-film solar cell is formed to have a large area.

### BRIEF DESCRIPTION OF DRAWINGS

FIG. 1 is a schematic cross-sectional view showing an example of the organic thin-film solar cell of the invention.

FIG. 2 is a schematic cross-sectional view showing another example of the organic thin-film solar cell of the invention.

FIGS. 3A to 3C are each a plan view showing examples of the shape of the mesh electrode in the organic thin-film solar cell of the invention.

FIGS. 4A to 9D are each a plan view showing further examples of the shape of the mesh electrode in the organic thin-film solar cell of the invention.

FIGS. 5A and 5B are each a plan view showing further examples of the shape of the mesh electrode in the organic thin-film solar cell of the invention.

FIGS. 6A and 6B are each a plan view showing further examples of the shape of the mesh electrode in the organic thin-film solar cell of the invention.

FIG. 7 is a schematic cross-sectional view showing a further example of the organic thin-film solar cell of the invention.

FIGS. 8A to 8F are a process diagram showing an example of the method for manufacturing the organic thin-film solar cell of the invention.

FIGS. 9A and 9B are each a view showing the result of a simulation performed on Example 4.

FIGS. 10A and 10B are each a view showing the result of a simulation performed on Example 4.

FIGS. 11A and 11B are each a view showing the result of a simulation performed on Example 4.

FIGS. 12A and 12B are each a view showing the result of a simulation performed on Example 4.

FIGS. 13A and 13B are each a view showing the result of a simulation performed on Example 4.

FIGS. 14A and 14B are a view showing the result of a simulation performed on Example 4.

FIGS. 15A and 15B are each a view showing the result of a simulation performed on Example 4.

FIGS. 16A and 16B are each a view showing the result of a simulation performed on Example 4.

FIGS. 17A and 17B are each a view showing the result of a simulation performed on Example 4.

FIGS. 18A and 18B are each a view showing the result of a simulation performed on Example 4.

FIGS. 19A and 19B are each a view showing the result of a simulation performed on Example 4.

FIG. 20 is a view showing the result of a simulation performed on Example 4.

FIG. 21 is a view showing the result of a simulation performed on Example 4.

FIG. 22 is a view showing the result of a simulation performed on Example 4.

### MODES FOR CARRYING OUT THE INVENTION

The organic thin-film solar cell of the invention and the method for manufacture thereof are described in detail below.

A. Organic Thin-Film Solar Cell

An organic thin-film solar cell of the invention comprises: a transparent substrate; a mesh electrode and a transparent electrode laminated in any order on the transparent substrate; a photoelectric conversion layer formed on the mesh electrode and the transparent electrode; and a counter electrode formed on the photoelectric conversion layer, wherein the mesh electrode has such a thickness that no short circuit occurs between the counter electrode and the mesh electrode and the transparent electrode.

The organic thin-film solar cell of the invention is described with reference to the drawings.

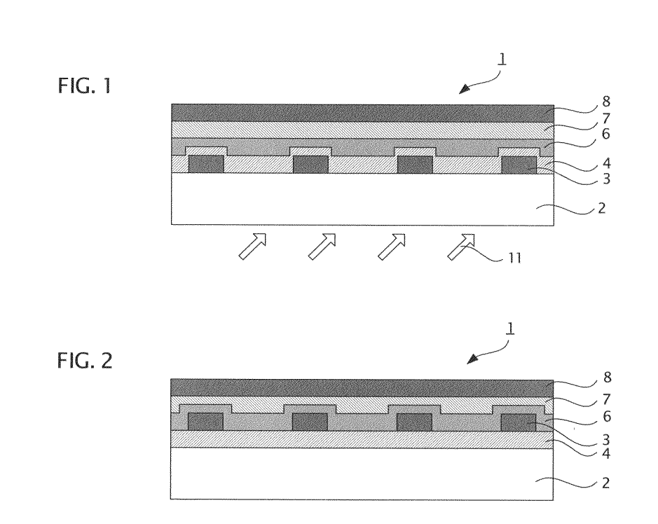

FIG. 1 is a schematic cross-sectional view showing an example of the organic thin-film solar cell of the invention. In the example shown in FIG. 1, an organic thin-film solar cell 1 comprises: a transparent substrate 2, a mesh electrode 3 formed on the transparent substrate 2, a transparent electrode 4 formed on the mesh electrode 3, a hole extraction layer 6 formed on the transparent electrode 4, a photoelectric conversion layer 7 formed on the hole extraction layer 6, and a counter electrode 8 formed on the photoelectric conversion layer 7. The mesh electrode 3 has such a thickness that no short circuit occurs between the counter electrode 8 and the mesh electrode 3 and the transparent electrode 4.

In the organic thin-film solar cell 1, incident light 11 from the openings of the mesh electrode 3 first generates charges in the photoelectric conversion layer 7. The generated charges (holes), which move in the thickness direction of the photoelectric conversion layer 7, are then extracted into the hole extraction layer 6 and into the transparent electrode 4 through the contact interface between the hole extraction layer 6 and the transparent electrode 4. On the other hand, the generated charges (electrons), which move in the thickness direction of the photoelectric conversion layer 7, are extracted into the counter electrode 8 through the contact interface between the photoelectric conversion layer 7 and the counter electrode 8.

According to the invention, the anode-side electrode is a laminate of the mesh electrode and the transparent electrode. Therefore, even when the transparent electrode has relatively high sheet resistance, the sheet resistance of the mesh electrode can be sufficiently reduced so that the sheet resistance of the entire anode can be reduced. Therefore, even when the organic thin-film solar cell is formed to have a large area, the generated electric power can be efficiently collected, so that high power generation efficiency can be maintained.

According to the invention, the thickness of the mesh electrode is such that no short circuit occurs between the counter electrode and the mesh electrode and the transparent electrode. Therefore, even in the organic thin-film solar cell having the mesh electrode, a short circuit is prevented from occurring between the electrodes.

Each component of the organic thin-film solar cell of the invention is described below.

1. Mesh Electrode and Transparent Electrode

The mesh electrode and the transparent electrode for use in the invention are laminated in any order on the transparent substrate. In the invention, the mesh electrode and the transparent electrode are on the light receiving side. The mesh electrode and the transparent electrode generally serve as electrodes to extract holes generated in the photoelectric conversion layer (hole extraction electrodes). A description is given below of the mesh electrode and the transparent electrode.

(1) Mesh Electrode

The mesh electrode for use in the invention is an electrode having a mesh structure, and the thickness of the mesh electrode is such that no short circuit occurs between the counter electrode and the mesh electrode and the transparent electrode.

The thickness of the mesh electrode is not restricted, as long as it is such that no short circuit occurs between the counter electrode and the mesh electrode and the transparent electrode, and it may be appropriately selected depending on the thickness of the photoelectric conversion layer, the hole extraction layer, the electron extraction layer, or the like. Specifically, when the total thickness of the layers formed between the counter electrode and the mesh electrode and the transparent electrode, such as the photoelectric conversion layer, the hole extraction layer and the electron extraction layer, is normalized as 1, the thickness of the mesh electrode is preferably 5 or less, more preferably 3 or less, even more preferably 1.5 or less. If the thickness of the mesh electrode exceeds the above range, a short circuit may occur between the electrodes. More specifically, the thickness of the mesh electrode is preferably in the range of 100 nm to 1,000 nm, in particular, preferably in the range of 200 nm to 800 nm. If the thickness of the mesh electrode is less than the above range, the sheet resistance of the mesh electrode may be too high, and if the thickness of the mesh electrode is more than the above range, a short circuit may occur between the electrodes.

Particularly when the photoelectric conversion layer is formed on the mesh electrode and the transparent electrode by a method capable of controlling the thickness mainly depending on the amount of coating, the thickness of the mesh electrode is preferably in the range of 200 nm to 300 nm.

The term “the amount of coating” means the thickness of coating. The “method capable of controlling the thickness mainly depending on the amount of coating” is a method that can control the thickness by controlling mainly the amount of coating, which is intended to exclude a method of controlling the thickness by controlling mainly a parameter other than the amount of coating, such as the number of revolutions (centrifugal force). The “method capable of controlling the thickness mainly depending on the amount of coating” may be any method that can control the thickness by controlling mainly the amount of coating (the thickness of coating), and specifically, the amount of coating (the thickness of coating) may be controlled by controlling factors such as the coating speed, the discharge amount, or the coating gap. Examples of the method capable of controlling the thickness mainly depending on the amount of coating include printing techniques such as die coating, bead coating, bar coating, gravure coating, inkjet process, screen printing, and offset printing. However, the method capable of controlling the thickness mainly depending on the amount of coating does not include spin coating.

When the photoelectric conversion layer is formed on the mesh electrode and the transparent electrode by the method capable of controlling the thickness mainly depending on the amount of coating, setting the thickness of the mesh electrode at more than the above range can make it difficult to cover the edge of the mesh electrode, so that a short circuit may be more likely to occur between the electrodes. Also if the thickness of the mesh electrode is more than the above range, the photoelectric conversion layer may be formed with a thickness greater than the desired thickness due to the surface tension. If the photoelectric conversion layer is too thick, it may exceed the electron diffusion length and the hole diffusion length, so that the conversion efficiency may be reduced. The thickness of the mesh electrode is preferably controlled so that the photoelectric conversion layer is prevented from being formed with a thickness greater than the desired thickness due to the surface tension. Particularly, the distance which holes and electrons can travel in a photoelectric conversion layer is known to be about 100 nm, and also from this point, the thickness of the mesh electrode is preferably controlled so that the photoelectric conversion layer is prevented from being formed with a thickness greater than the desired thickness due to the surface tension.

On the other hand, for example, when the photoelectric conversion layer is formed by spin coating, the centrifugal force can make the film uniform, so that the edge of the mesh electrode can be covered even when the mesh electrode is relatively thick. In the case of spin coating, the thickness can also be controlled by the number of revolutions, which makes it possible to obtain a uniform film even when the mesh electrode is relatively thick.

Thus, when the photoelectric conversion layer is formed by the method capable of controlling the thickness mainly depending on the amount of coating, the above range is particularly preferred.

The material used to form the mesh electrode is generally metal. Examples of the metal used to form the mesh electrode include electrically conductive metals such as aluminum (Al), gold (Au), silver (Ag), cobalt (Co), nickel (Ni), platinum (Pt), copper (Cu), titanium (Ti), aluminum alloys, titanium alloys, and nickel-chromium (Ni—Cr) alloys. Among these electrically conductive metals, metals with relatively low electrical resistance are preferred. Such electrically conductive metals include Al, Au, Ag, and Cu.

The mesh electrode may be a single layer made of the electrically conductive metal as described above or a laminate of an electrically conductive metal layer and a contact layer, which are appropriately laminated to improve bonding to the transparent substrate or the transparent electrode. Examples of the material used to form the contact layer include nickel (Ni), chromium (Cr), titanium (Ti), tantalum (Ta), and nickel-chromium (Ni—Cr). The contact layer is laminated on the electrically conductive metal layer so that a desired bonding between the mesh electrode and the transparent substrate or the transparent electrode can be obtained, and the contact layer or layers may be placed on only one or both sides of the electrically conductive metal layer.

A preferred metal may be selected depending on a factor such as the work function of the counter electrode-forming material. For example, when the work function of the counter electrode-forming material is taken into account, it is preferred that the metal should have a high work function, because the mesh electrode serves as a hole extraction electrode. Specifically, Al is preferably used.

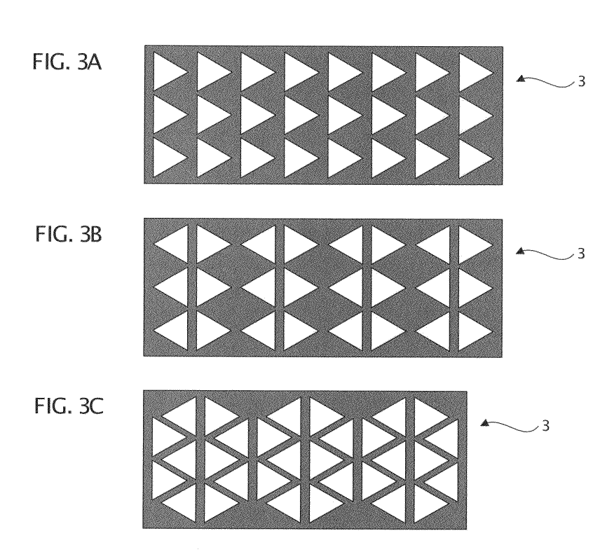

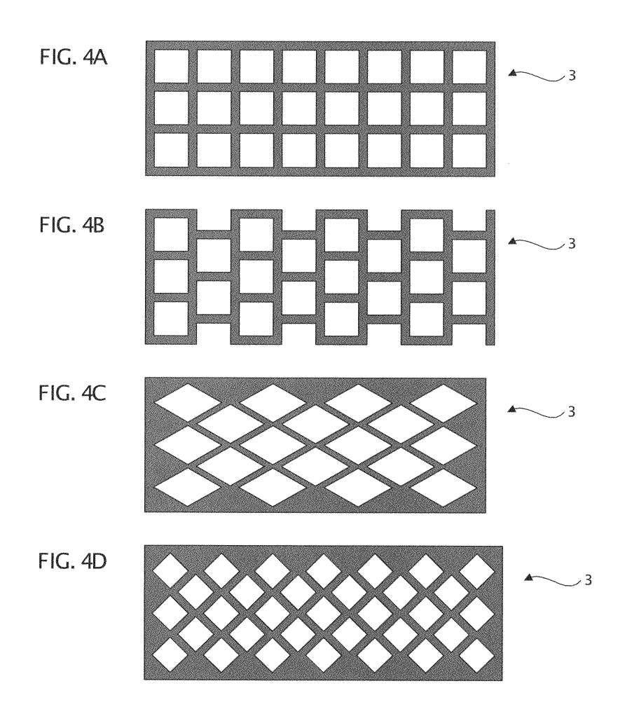

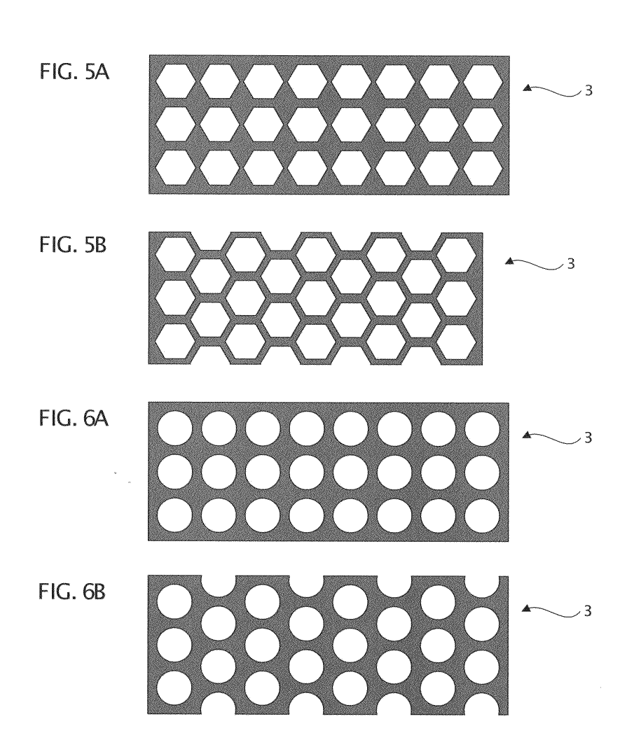

The mesh electrode may be of any shape as long as it has a mesh structure, and the shape of the mesh electrode is appropriately selected depending on factors such as a desired conductivity, transparency, and strength. For example, it may be a polygonal or circular lattice shape. FIGS. 3 to 6 show some examples of the shape of the mesh electrode 3. FIGS. 3A to 3C show the case of a triangular lattice shape. In FIGS. 3A and 3B, triangular openings are straightly arranged, and in FIG. 3C, triangular openings are zigzag arranged. FIGS. 4A to 4D show the case of a quadrangular lattice shape. In FIG. 4A, rectangular openings are straightly arranged; in FIG. 4B, rectangular openings are zigzag arranged; in FIG. 4C, rhomboidal (angle≠90°) openings are arranged; and in FIG. 4D, rhomboidal (square) openings are arranged. FIGS. 5A and 5B show the case of a hexagonal lattice shape. In FIG. 5A, hexagonal openings are straightly arranged; and in FIG. 5B, hexagonal openings are zigzag arranged, namely, arranged in a so-called honeycomb pattern. FIGS. 6A and 6B show the case of a circular lattice shape. In FIG. 6A, circular openings are straightly arranged; and in FIG. 6B, circular openings are zigzag arranged. The polygonal or circular “lattice shape” means a structure in which polygons or circles are periodically arranged.

In particular, the mesh electrode preferably has a hexagonal or parallelogram lattice shape. This is because a current flowing through the mesh electrode can be prevented from being localized. For example, the current flow may be concentrated in a specific direction so that a low current region may occur. In such case, openings may be placed at such a low current region, which makes it possible to increase the opening ratio, the amount of incident light, and the photoelectric conversion efficiency. The existence of a low current region means that the photoelectric conversion efficiency is reduced. Therefore, the mesh electrode is preferably so shaped that the current flowing through the mesh electrode can be prevented from being localized. Also if the current flow is concentrated only in a specific direction, the mesh electrode may be locally heated, so that the transparent substrate or the photoelectric conversion layer formed adjacent to the mesh electrode can be damaged by heat and reduced in durability. Therefore, when the mesh electrode is shaped as described above, the current flowing through the mesh electrode can be prevented from being localized, so that the mesh electrode can be prevented from being locally heated and therefore can have increased durability.

In the organic thin-film solar cell of the invention, charges generated in the photoelectric conversion layer are transported by the mesh electrode. In this process, the charges are considered to be transported radially. In the case of a hexagonal lattice shape or a parallelogram lattice shape, the current distribution can be made relatively uniform when the current is radially collected.

In the case of a hexagonal lattice shape, in particular, hexagonal openings are preferably arranged in a honeycomb pattern as illustrated in FIG. 5B. In this case, the current flowing through the mesh electrode can be effectively prevented from being localized.

In the case of a parallelogram lattice shape, the parallelogram preferably has an acute angle in the range of 40° to 80°, more preferably in the range of 50° to 70°, and even more preferably in the range of 55° to 65°. The lengths of the four sides of the parallelogram are appropriately determined depending on the external form of the solar cell. Specifically, when the parallelogram is a rhombus with four equal sides and with an acute angle of 60° and an obtuse angle of 120°, the uniform-current area in which the current distribution is relatively uniform has an elliptical shape in which the current is more likely to flow in the direction of a diagonal between the acute corners of the parallelogram. Therefore, the lengths of the four sides of the parallelogram are appropriately determined, taking into account the distance from the center of the solar cell to the periphery of the mesh electrode, which can form a peripheral electrode.

Since the mesh electrode itself basically does not transmit light, the light enters the photoelectric conversion layer from the openings of the mesh electrode. Therefore, the mesh electrode preferably has relatively large openings. Specifically, the mesh electrode preferably has an opening ratio in the range of about 50% to about 98%, more preferably in the range of 70% to 98%, and even more preferably in the range of 80% to 98%.

In particular, when the mesh electrode has a thickness of 200 nm to 300 nm, it preferably has an opening ratio in the range of 80% to 98%, and more preferably in the range of 85% to 98%. On the other hand, when the mesh electrode has a thickness of 100 nm to 200 nm, it preferably has an opening ratio in the range of 70% to 80%, and more preferably in the range of 75% to 80%.

When the mesh electrode has a hexagonal lattice shape, the opening ratio is preferably in the range of 70% to 80%, and more preferably in the range of 75% to 80%. On the other hand, when the mesh electrode has a parallelogram lattice shape, the opening ratio is preferably in the range of 80% to 98%, and more preferably in the range of 85% to 98%.

If the opening ratio is less than the above range, light may be insufficiently transmitted so that the photoelectric conversion efficiency may be reduced, although the line width of the mesh electrode can be increased so that the mesh electrode can have an increased area and a reduced resistance. If the opening ratio is more than the above range, the line width and the area of the mesh electrode may be so small that the mesh electrode may have reduced charge transfer efficiency and increased resistance, although light can be sufficiently transmitted to increase the photoelectric conversion efficiency. In addition, it is difficult to stably form the electrode if the opening ratio is too high. When the opening ratio is too high, the mesh electrode has to be formed thick enough to have a desired resistance value, which may reduce the production efficiency or make it difficult to form a continuous film of the photoelectric conversion layer because the mesh electrode forms a high step.

The pitch of the openings of the mesh electrode and the line width of the mesh electrode may be appropriately selected depending on factors such as the area of the whole of the mesh electrode.

The mesh electrode preferably has a sheet resistance of 5 Ω/square or less, more preferably 3 Ω/square or less, and in particular, preferably 1 Ω/square or less. If the sheet resistance of the mesh electrode is more than the above range, a desired power generation efficiency cannot be obtained in some cases.

The sheet resistance is a value measured according to JIS R 1637 (Test Method for Resistivity of Fine Ceramic Thin Films with a Four-Point Probe Method) using a surface resistance meter manufactured by Mitsubishi Chemical Corporation (Loresta MCP™: four-terminal probe).

Concerning the position where the mesh electrode is formed, the mesh electrode 3 and the transparent electrode 4 may be formed in this order on the transparent substrate 2 as illustrated in FIG. 1, or the transparent electrode 4 and the mesh electrode 3 may be formed in this order on the transparent substrate 2 as illustrated in FIG. 2. In particular, the mesh electrode and the transparent electrode are preferably formed in this order on the transparent substrate. This is because a large contact area between the transparent electrode and the photoelectric conversion layer or the hole extraction layer or the like can provide good bonding at the interface and achieve high hole transfer efficiency.

The method of forming the mesh electrode is typically, but not limited to, a method of forming a metal thin film on the entire surface and then patterning the film into a mesh structure, or a method of directly forming a mesh conductor. These methods are appropriately selected depending on factors such as the mesh electrode forming material or structure.

The metal thin film is preferably formed by a vacuum film forming method such as vacuum deposition, sputtering or ion plating. Therefore, the mesh electrode is preferably a metal thin film formed by the vacuum film forming method. Metal species formed by the vacuum film forming method can have a lower inclusion content and a lower specific resistance than plating films. The metal thin film formed by the vacuum film forming method can also have a lower specific resistance than films produced with a Ag paste or the like. The vacuum film forming method is also preferred for forming a metal thin film with a uniform thickness of 1 μm or less while controlling the thickness with high precision.

The metal thin film may be patterned by any method capable of forming a desired pattern with high precision, and an example of which is photo-etching.

(2) Transparent Electrode

The transparent electrode forming material for use in the invention may be any material having electrical conductivity and transparency, such as In—Zn—O (IZO), In—Sn—O (ITO), ZnO—Al, or Zn—Sn—O. In particular, it is preferably selected taking into account the work function of the counter electrode forming material described below. For example, when the counter electrode forming material has a low work function, the transparent electrode forming material preferably has a high work function. ITO is preferably used as a material having electrical conductivity, transparency, and a high work function.

The transparent electrode preferably has a total light transmittance of 85% or more, more preferably 90% or more, and in particular, preferably 92% or more. When the total light transmittance of the transparent electrode is in the above range, the transparent electrode can sufficiently transmit light so that the photoelectric conversion layer can efficiently absorb light.

The total light transmittance is a value measured using SM Color Computer manufactured by Suga Test Instruments Co., Ltd. (Model: SM-C) in the visible light region.

The transparent electrode preferably has a sheet resistance of 20 Ω/square or less, more preferably 10 Ω/square or less, and in particular, preferably 5 Ω/square or less. If the sheet resistance is more than the above range, the generated charges may fail to be transferred to the external circuit sufficiently.

The sheet resistance is a value measured according to JIS R 1637 (Test Method for Resistivity of Fine Ceramic Thin Films with a Four-Point Probe Method) using a surface resistance meter manufactured by Mitsubishi Chemical Corporation (Loresta MCP™: four-terminal probe).

The transparent electrode may be a single layer or a laminate of materials with different work functions.

The thickness of the transparent electrode, which corresponds to the thickness of a single layer or the total thickness of two or more layers, is preferably in the range of 0.1 nm to 500 nm, and in particular, preferably in the range of 1 nm to 300 nm. If the thickness is less than the above range, the transparent electrode may have too high sheet resistance, so that the generated charges may fail to be transferred to the external circuit sufficiently. If the thickness is more than the above range, the total light transmittance may be reduced, so that the photoelectric conversion efficiency may be reduced.

The transparent electrode may be formed over the entire surface of the substrate or formed in a certain pattern on the substrate.

The transparent electrode may be formed using a general electrode forming method.

2. Photoelectric Conversion Layer

The photoelectric conversion layer for use in the invention is formed between the counter electrode and the mesh electrode and the transparent electrode. The term “photoelectric conversion layer” refers to an element having the function of contributing to charge separation in the organic thin-film solar cell and transporting the generated electrons and holes to the opposite electrodes, respectively.

The photoelectric conversion layer may be a single layer having both an electron-accepting function and an electron-donating function (first mode) or a laminate of an electron-accepting layer having the function of accepting electrons and an electron-donating layer having the function of donating electrons (second mode). A description is given below of each mode.

(1) First Mode

A first mode of the photoelectric conversion layer according to the invention is a single layer having both an electron-accepting function and an electron-donating function and contains an electron-accepting material and an electron-donating material. In this photoelectric conversion layer, charge separation is generated based on a pn junction formed therein, so that the photoelectric conversion layer functions by itself.

While the electron-donating material may be any material as long as the material has a function of an electron donor, it is preferably a material capable of being formed into a film by a wet coating method, and in particular, it is preferably an electron-donating, electrically-conductive polymer material.

Electrically-conductive polymers are so-called π-conjugated polymers, which include a π-conjugated system, in which a single bond and a double or triple bond containing carbon-carbon or a hetero atom are alternately linked, and exhibit semiconducting properties. The electrically-conductive polymer material has developed π conjugation in the polymer main chain and therefore is basically advantageous in transporting charges in the direction of the main chain. The electron transfer mechanism of the electrically-conductive polymers is mainly hopping conduction between π-stacked molecules, and therefore, the electrically-conductive polymers are advantageous in transporting charges not only in the direction of the polymer main chain but also in the direction of the thickness of the photoelectric conversion layer. In addition, the electrically-conductive polymer material can be easily formed into a film by a wet coating method using a coating liquid in which the electrically-conductive polymer material is dissolved or dispersed in a solvent. Therefore, the electrically-conductive polymer material has the advantage that large-area organic thin-film solar cells can be manufactured using the electrically-conductive polymer material at low cost without the need for expensive equipment.

Examples of the electron-donating, electrically-conductive polymer material include polyphenylene, polyphenylene vinylene, polysilane, polythiophene, polycarbazole, polyvinylcarbazole, porphyrin, polyacetylene, polypyrrole, polyaniline, polyfluorene, polyvinylpyrene, polyvinyl anthracene, derivatives thereof, and copolymers thereof, or phthalocyanine-containing polymers, carbazole-containing polymers, and organometallic polymers.

Among the above, preferably used are thiophene-fluorene copolymers, polyalkylthiophene, phenylene ethynylene-phenylene vinylene copolymers, phenylene ethynylene-thiophene copolymers, phenylene ethynylene-fluorene copolymers, fluorene-phenylene vinylene copolymers, and thiophene-phenylene vinylene copolymers. These are appropriately different in energy level from many electron-accepting materials.

For example, a detailed method for synthesis of a phenylene ethynylene-phenylene vinylene copolymer (poly[1,4-phenyleneethynylene-1,4-(2,5-dioctadodecyloxyphenylene)-1,4-phenyleneethene-1,2-diyl-1,4-(2,5-dioctadodecyloxyphenylene)ethene-1,2-diyl]) is described in Macromolecules, 35, 3825 (2002) or Mcromol. Chem. Phys., 202, 2712 (2001).

While the electron-accepting material may be any material as long as the material has a function of an electron acceptor, it is preferably a material capable of being formed into a film by a wet coating method, and in particular, it is preferably an electron-accepting, electrically-conductive polymer material. Such an electrically-conductive polymer material has the advantage described above.

Examples of the electron-accepting, electrically-conductive polymer material include polyphenylene vinylene, polyfluorene, derivatives thereof, and copolymers thereof, or carbon nanotubes, fullerene derivatives, CN or CF₃ group-containing polymers, and —CF₃ substituted polymers thereof. Examples of the polyphenylene vinylene derivatives include CN-PPV (poly[2-methoxy-5-(2′-ethylhexyloxy)-1,4-(1-cyanovinylene)phenylene]) and MEH-CN-PPV (poly[2-methoxy-5-(2′-ethylhexyloxy)-1,4-(1-cyanovinylene)phenylene].

An electron-accepting material doped with an electron-donating compound or an electron-donating material doped with an electron-accepting compound may also be used. In particular, an electrically-conductive polymer material doped with an electron-donating compound or an electron-accepting compound is preferably used. The electrically-conductive polymer material has developed n conjugation in the polymer main chain and therefore is basically advantageous in transporting charges in the direction of the main chain. In addition, when doped with an electron-donating or -accepting compound, the electrically-conductive polymer material generates charges in the π-conjugated main chain, so as to have significantly increased electric conductivity.

The electron-accepting, electrically-conductive polymer material described above may be doped with an electron-donating compound. Examples of the electron-donating compound that may be used for doping include Lewis bases such as alkali metals and alkaline earth metals such as Li, K, Ca, and Cs. Such Lewis bases act as electron donors.

The electron-donating, electrically-conductive polymer material described above may be doped with an electron-accepting compound. Examples of the electron-accepting compound that may be used for doping include Lewis acids such as halogen compounds like FeCl₃(III) , AlCl₃, AlBr₃, and AsF₆. Such Lewis acids act as electron acceptors.

The photoelectric conversion layer may have a thickness that is generally used in bulk hetero-junction organic thin-film solar cells. Specifically, the thickness may be set in the range of 0.2 nm to 3,000 nm, and preferably in the range of 1 nm to 600 nm. If the thickness is more than the above range, the photoelectric conversion layer may have relatively high volume resistance. If the thickness is less than the above range, the layer may fail to absorb a sufficient amount of light.

The mixing ratio of the electron-donating material and the electron-accepting material is optimized as needed depending on the type of the materials used.

While the photoelectric conversion layer may be formed by any method capable of uniformly forming a film with a desired thickness, a wet coating method is preferably used to form it. In the wet coating method, the photoelectric conversion layer can be formed in the air, which makes it possible to achieve cost savings and makes it easy to form a large-area layer.

A coating liquid for forming the photoelectric conversion layer may be applied by any method capable of uniformly applying the coating liquid, and examples of which include die coating, spin coating, dip coating, roll coating, bead coating, spray coating, bar coating, gravure coating, inkjet process, screen printing, and offset printing.

In particular, the method of applying the coating liquid for the photoelectric conversion layer is preferably a method capable of controlling the thickness mainly depending on the amount of coating. Examples of the method capable of controlling the thickness mainly depending on the amount of coating include printing techniques such as die coating, bead coating, bar coating, gravure coating, inkjet process, screen printing, and offset printing. The printing techniques are suitable for forming large-area, organic thin-film solar cells.

After the photoelectric conversion layer coating liquid is applied, the resulting coating film may be subjected to a drying process. When the solvent and the like contained in the photoelectric conversion layer coating liquid is quickly removed, the productivity can be increased.

For example, the drying process may be performed using a general method such as drying by heating, air blow drying, vacuum drying, or drying by infrared heating.

(2) Second Mode

A second mode of the photoelectric conversion layer according to the invention is a laminate of an electron-accepting layer having the function of accepting electrons and an electron-donating layer having the function of donating electrons. A description is given below of the electron-accepting layer and the electron-donating layer.

(Electron-Accepting Layer)

The electron-accepting layer for use in this mode has the function of accepting electrons and contains an electron-accepting material.

While the electron-accepting material may be any material as long as the material has a function of an electron acceptor, it is preferably a material capable of being formed into a film by a wet coating method, and in particular, it is preferably an electron-accepting, electrically-conductive polymer material. Such an electrically-conductive polymer material has the advantage described above. Specific examples include the same electron-accepting, electrically-conductive polymer materials as those used for the photoelectric conversion layer in the first mode.

The electron-accepting layer may have a thickness that is generally used in bilayer organic thin-film solar cells. Specifically, the thickness may be set in the range of 0.1 nm to 1,500 nm, and preferably in the range of 1 nm to 300 nm. If the thickness is more than the above range, the electron-accepting layer may have relatively high volume resistance. If the thickness is less than the above range, the layer may fail to absorb a sufficient amount of light.

The electron-accepting layer may be formed by the same method as the method of forming the photoelectric conversion layer of the first mode.

(Electron-Donating Layer)

The electron-donating layer for use in the invention has the function of donating electrons and contains an electron-donating material.

While the electron-donating material may be any material as long as the material has a function of an electron donor, it is preferably a material capable of being formed into a film by a wet coating method, and in particular, it is preferably an electron-donating, electrically-conductive polymer material. Such an electrically-conductive polymer material has the advantage described above. Specific examples include the same electron-donating, electrically-conductive polymer materials as those used for the photoelectric conversion layer in the first mode.

The electron-donating layer may have a thickness that is generally used in bilayer organic thin-film solar cells. Specifically, the thickness may be set in the range of 0.1 nm to 1,500 nm, and preferably in the range of 1 nm to 300 nm. If the thickness is more than the above range, the electron-donating layer may have relatively high volume resistance. If the thickness is less than the above range, the layer may fail to absorb a sufficient amount of light.

The electron-donating layer may be formed by the same method as the method of forming the photoelectric conversion layer of the first mode.

3. Counter Electrode

The counter electrode used in the invention is an electrode opposed to the mesh electrode and the transparent electrode. In general, the counter electrode is formed as an electrode for extracting electrons generated in the photoelectric conversion layer (electron extraction electrode). In the invention, the counter electrode does not have to have transparency, because the mesh electrode and the transparent electrode are placed on the light-receiving side.

While the counter electrode forming material may be any material having electrical conductivity, it preferably has a low work function, because the counter electrode serves as an electron extraction electrode. Examples of low work function materials include Li, In, Al, Ca, Mg, Sm, Tb, Yb, Zr, and LiF.

The counter electrode may be a single layer or a laminate of materials with different work functions.

The thickness of the counter electrode, which corresponds to the thickness of a single layer or the total thickness of two or more layers, is preferably in the range of 0.1 nm to 500 nm, and in particular preferably in the range of 1 nm to 300 nm. If the thickness is less than the above range, the counter electrode may have too high sheet resistance, so that the generated charges may fail to be transferred to the external circuit sufficiently.

The counter electrode may be formed over the entire surface of the photoelectric conversion layer or formed in a certain pattern on the photoelectric conversion layer.

The counter electrode may be formed using a general electrode-forming method such as vacuum deposition or patterned vapor deposition with a metal mask.

4. Transparent Substrate

The transparent substrate for use in the invention may be of any type, and examples of which include a non-flexible transparent rigid member such as a quartz glass, PYREX (registered trademark), or synthetic quart plate; or a flexible transparent member such as a transparent resin film or an optical resin plate.

In particular, the transparent substrate is preferably a flexible member such as a transparent resin film. The transparent resin film has good workability, is useful for reducing the manufacturing cost or the weight and for forming a crack-resistant organic thin-film solar cell, and therefore can be used in a wide variety of applications including curved surface applications.

5. Hole Extraction Layer

In the invention, as illustrated in FIG. 1, the hole extraction layer 6 is preferably formed between the photoelectric conversion layer 7 and the mesh electrode 3 and the transparent electrode 4 (hole extraction electrode). The hole extraction layer is provided to facilitate the extraction of holes from the photoelectric conversion layer to the hole extraction electrode. This increases the efficiency of the extraction of holes from the photoelectric conversion layer to the hole extraction electrode, so that the photoelectric conversion efficiency can be increased.

The material used to form the hole extraction layer may be any material capable of stabilizing the extraction of holes from the photoelectric conversion layer to the hole extraction electrode. Examples include electrically-conductive organic compounds such as doped polyaniline, polyphenylene vinylene, polythiophene, polypyrrole, polyparaphenylene, polyacetylene, and triphenyldiamine (TPD); and organic materials that form a charge transfer complex composed of an electron-donating compound such as tetrathiofulvalene or tetramethylphenylenediamine and an electron-accepting compound such as tetracyanoquinodimethane or tetracyanoethylene. A thin film of a metal or the like such as Au, In, Ag, or Pd may also be used. The thin film of a metal or the like may be used alone or in combination with the above-mentioned organic materials.

In particular, polyethylenedioxythiophene (PEDOT) or triphenyldiamine (TPD) is preferably used.

The thickness of the hole extraction layer is preferably in the range of 10 nm to 200 nm when the organic materials are used or preferably in the range of 0.1 nm to 5 nm when the metal thin film is used.

6. Electron Extraction Layer

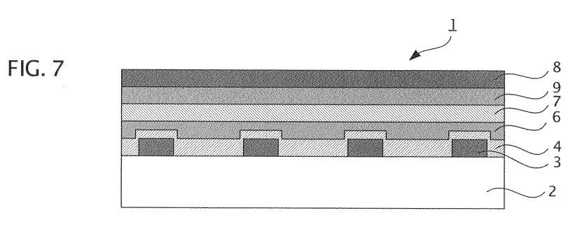

In the invention, as illustrated in FIG. 7, an electron extraction layer 9 may be formed between the photoelectric conversion layer 7 and the counter electrode 8 (electron extraction electrode). The electron extraction layer is provided to facilitate the extraction of electrons from the photoelectric conversion layer to the electron extraction electrode. This increases the efficiency of the extraction of electrons from the photoelectric conversion layer to the electron extraction electrode, so that the photoelectric conversion efficiency can be increased.

The material used to form the electron extraction layer may be any material capable of stabilizing the extraction of electrons from the photoelectric conversion layer to the electron extraction electrode. Examples include electrically-conductive organic compounds such as doped polyaniline, polyphenylene vinylene, polythiophene, polypyrrole, polyparaphenylene, polyacetylene, and triphenyldiamine (TPD); and organic materials that form a charge transfer complex composed of an electron-donating compound such as tetrathiofulvalene or tetramethylphenylenediamine and an electron-accepting compound such as tetracyanoquinodimethane or tetracyanoethylene. A metal-doped layer with an alkali metal or an alkaline earth metal may also be used. Preferred materials include metal-doped layers including bathocuproine (BCP) or bathophenanthron (Bphen) and Li, Cs, Ba, Sr, or the like.

7. Other Features

The organic thin-film solar cell of the invention exhibits good power generation efficiency even when having a large area. The area of the organic thin-film solar cell is preferably, but not limited to, 50 mm square or more.

In addition to the components described above, if necessary, the organic thin-film solar cell of the invention may have any of the components mentioned below. For example, the organic thin-film solar cell of the invention may have a functional layer such as a protective sheet, a filler layer, a barrier layer, a protective hard-coat layer, a strength supporting layer, an anti-fouling layer, a high light-refection layer, a light confining layer, or a sealer layer. A bonding layer may also be formed between the respective functional layers depending on the layered structure.

These functional layers may be those disclosed in publications such as JP-A No. 2007-73717.

B. Method for Manufacturing Organic Thin-Film Solar Cell

The method for manufacturing the organic thin-film solar cell of the invention is a manufacturing method, in which an organic thin-film solar cell comprises: a transparent substrate, a mesh electrode and a transparent electrode laminated in any order on the transparent substrate, a photoelectric conversion layer formed on the mesh electrode and the transparent electrode, and a counter electrode formed on the photoelectric conversion layer, and the method comprises: a mesh electrode-forming step of forming a metal thin film on the transparent substrate; placing a resist on the metal thin film; and pattering the metal thin film into a mesh structure by a photo-etching method to form the mesh electrode.

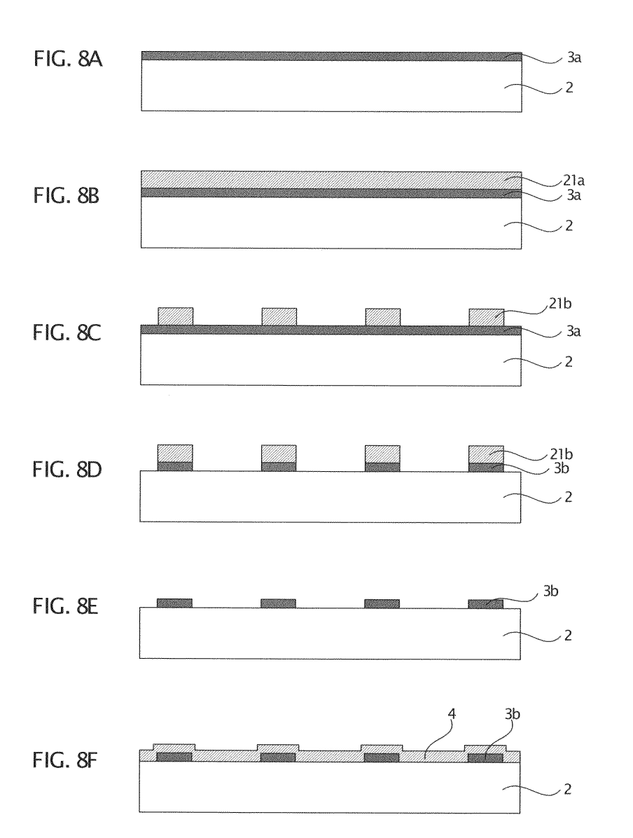

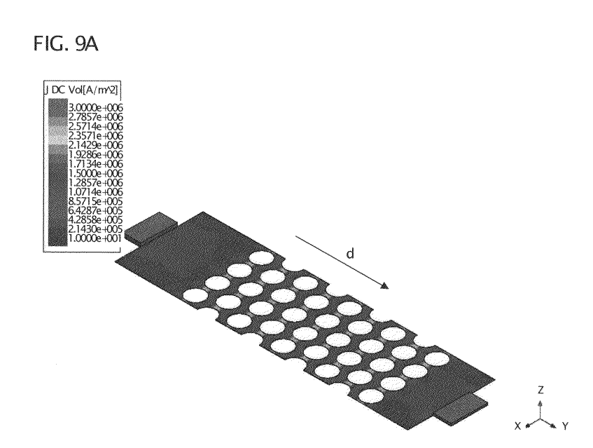

FIGS. 8A to 8F are a process diagram showing an example of the method for manufacturing the organic thin-film solar cell of the invention.

First, a metal thin film 3a is formed on the entire surface of a transparent substrate 2 (FIG. 8A). A resist 21a is then placed on the metal thin film 3a (FIG. 8B) and subjected to exposure and development so that a resist image 21b is formed (FIG. 8C). The exposed part of the metal thin film 3a is then etched using the resist image 21a as a mask (FIG. 8D), and the resist image 21b is removed so that a mesh electrode 3b is formed (FIG. 8E). A transparent electrically-conductive film is then formed as a transparent electrode 4 on the mesh electrode 3b (FIG. 8F). Subsequently, although not shown, a hole extraction layer and a photoelectric conversion layer are formed on the transparent electrode, and a counter electrode is formed on the photoelectric conversion layer, so that an organic thin-film solar cell 1 as illustrated in FIG. 1 is obtained.

When the mesh electrode is formed, the transparent electrode may be first formed on the transparent substrate, and then the mesh electrode may be formed on the transparent electrode. In this case, the organic thin-film solar cell 1 as illustrated in FIG. 2 is obtained.

If necessary, an electron extraction layer may be formed on the photoelectric conversion layer, and the counter electrode may be formed on the electron extraction layer. In this case, the organic thin-film solar cell 1 as illustrated in FIG. 7 is obtained.

According to the invention, the mesh electrode is formed by a photo-etching method. Therefore, even when the metal thin film is relatively thin, it can be pattered into a desired shape so that a thin mesh electrode can be formed. Thus, the thickness of the mesh electrode can be made such that no short circuit occurs between the electrodes. This makes it possible to obtain the organic thin-film solar cell in which a short circuit hardly occurs between the electrodes.

According to the invention, the mesh electrode and the transparent electrode are laminated to form an anode-side electrode. Therefore, even when the sheet resistance of the transparent electrode is relatively high, the sheet resistance of the entire anode can be reduced. Therefore, even when the organic thin-film solar cell having a large area is manufactured, the resulting organic thin-film solar cell exhibits good power generation efficiency.

Since the transparent substrate, the transparent electrode and the method of forming the same, the counter electrode and the method of forming the same, the hole extraction layer and the method of forming the same, and the electron extraction layer and the method of forming the same, and so on are described in the section “A. Organic Thin-Film Solar Cell,” and therefore a repeated description thereof is omitted here.

A description is given below of the mesh electrode-forming step in the method for manufacturing an organic thin-film solar cell of the invention.

1. Mesh Electrode-Forming Step

In the invention, the mesh electrode-forming step of forming a metal thin film on a transparent substrate, placing a resist on the metal thin film, and pattering the metal thin film into a mesh structure by a photo-etching method to form a mesh electrode.

The metal thin film-forming material is the same as the mesh electrode-forming material described in the mesh electrode part of the section “A. Organic Thin-Film Solar Cell.”

For example, the metal thin film may be formed by vacuum deposition, sputtering, or ion plating.

In the invention, a general resist for forming electrodes may be used.

General methods may be used in the exposure and development of the resist.

After the exposure and development of the resist, an unnecessary part of the metal thin film is removed by etching so that the metal thin film is patterned into a desired shape.

In this process, the metal thin film may be patterned into any desired mesh shape, which may be appropriately selected depending on factors such as a desired electrical conductivity, transparency, and strength. For example, it may be a polygonal or circular lattice shape. In particular, the metal thin film is preferably patterned into a hexagonal lattice shape or a parallelogram lattice shape. The shapes are the same as those described in the mesh electrode part of the section “A. Organic Thin-Film Solar Cell.”

After the metal thin film is etched, the resist is removed. A general method may be used to remove the resist.

The resulting mesh electrode is described in detail in the above section “A. Organic Thin-Film Solar Cell,” and therefore a repeated description thereof is omitted here.

2. Photoelectric Conversion Layer-Forming Step

In the invention, the mesh electrode-forming step is generally followed by photoelectric conversion layer-forming step in which the photoelectric conversion layer is formed.

In this step, the photoelectric conversion layer is preferably formed by a method capable of controlling the thickness mainly depending on the amount of coating. This method is suitable for forming a large-area organic thin-film solar cell.

The photoelectric conversion layer, the method of forming the same and so on are described in the above section “A. Organic Thin-Film Solar Cell,” and therefore a repeated description thereof is omitted here.

The above embodiments are not intended to limit the scope of the invention. The above embodiment is described by way of example only, and it will be understood that many variations are possible with substantially the same feature as recited in the claims to produce the same effect, and all of such variations are within the technical scope of the invention.

### EXAMPLES

The invention is more specifically described by the examples below.

### Example 1

Ni/Cu/Ni (20 nm/300 nm/20 nm in thickness) were laminated on one entire surface of a PEN film substrate with an outside size of 50 mm square and a thickness of 125 μm by sputtering (production pressure: 0.1 Pa, production power: 180 W, production time: 3 minutes/12 minutes/3 minutes). A dry film resist (SUNFORT AQ-1558™, negative type, Asahi Kasei Corporation) was laminated on the entire surface of the Ni/Cu/Ni film under a laminating pressure of 0.4 kgf/cm² at a temperature of 120° C., and UV irradiation was performed through a photomask of a specific pattern, so that a desired pattern was transferred onto the dry film resist. Subsequently, the unexposed part of the resist was removed in an aqueous 0.5 wt % sodium carbonate solution, so that a resist image of a desired pattern was formed. The exposed part of the Ni/Cu/Ni film was etched with a ferric chloride solution (45 Baume) at a temperature of 50° C. through the resist image used as a mask. The time required to etch the Ni/Cu/Ni film was 3 seconds. Subsequently, the resist was removed using a 2 wt % sodium hydroxide solution at a temperature of 50° C., so that an Ni/Cu/Ni metal mesh having desired openings was formed.

An ITO film (thickness: 150 nm, sheet resistance: 20 Ω/square) as a transparent electrode was formed on the upper surface of the metal mesh by reactive ion plating (power: 3.7 kW, oxygen partial pressure: 73%, production pressure: 0.3 Pa, production rate: 150 nm/minute, substrate temperature: 20° C.) using a pressure gradient plasma gun. The ITO film-carrying substrate was then washed with acetone, a substrate cleaning solution, and IPA. This process reduced the apparent sheet resistance of the ITO electrode (the sheet resistance of a laminate of the ITO electrode and the metal mesh) to 0.1 Ω/square.

Subsequently, a film of an electrically-conductive polymer paste (a poly-(3,4-ethylenedioxythiophene) dispersion) was formed by spin coating on the ITO film-carrying substrate, and then dried at 150° C. for 30 minutes to form a hole extraction layer (thickness: 100 nm).

A polythiophene (P3HT: poly(3-hexylthiophene-2,5-diyl)) and C60PCBM ([6,6]-phenyl-C61-butyric acid mettric ester) were then dissolved in bromobenzene to form a photoelectric conversion layer coating liquid with a solids content of 1.4 wt %. Subsequently, the photoelectric conversion layer coating liquid was applied to the hole extraction layer by spin coating at a rotation speed of 600 rpm to form a photoelectric conversion layer. The photoelectric conversion layer-carrying substrate was then exposed to the air.

Ca/Al (60 nm/200 nm in thickness) was then formed as a metal electrode on the photoelectric conversion layer by vacuum deposition.

The substrate having the photoelectric conversion layer and so on formed thereon was then dried by heating on a hot plate at a temperature of 150° C. Finally, sealing was performed with a sealing glass material and an adhesive sealing material from the top of the metal electrode, so that an organic thin-film solar cell was obtained.

### Example 2

An organic thin-film solar cell was prepared as in Example 1, except that the ITO electrode and the metal mesh were formed in this order on the PEN film substrate.

### Comparative Example 1

An organic thin-film solar cell was prepared as in Example 1, except that the metal mesh was not formed.

[Evaluation]

Power generation evaluation was performed on the organic thin-film solar cells of Examples 1 and 2 (the apparent sheet resistance of the ITO electrode: 0.1 Ω/square) and the organic thin-film solar cell of Comparative Example 1 (the sheet resistance of the ITO electrode: 20 Ω/square). In the evaluation method, the current-voltage characteristics were evaluated using an AM 1.5 solar simulator (100 mW/cm²) as the light source and a source measure unit (HP4100™ manufactured by Hewlett-Packard Development Company, L.P.) for the voltage application.

The power generation efficiency of the organic thin-film solar cell of Comparative Example 1 was 0.05%. On the other hand, the power generation efficiency was increased to 2.2% in the organic thin-film solar cell of Example 1 and to 1.5% in the organic thin-film solar cell of Example 2. It was demonstrated that when a very thin metal mesh was placed on the ITO electrode, the optical transparency was reduced, but the power loss was reduced with the reduction in the apparent sheet resistance of the ITO electrode, so that the conversion efficiency was increased.

### Reference Examples 1 to 3

Cr/Cu (60 nm/300 nm in thickness) were laminated on one entire surface of a PEN film substrate with an outside size of 50 mm square and a thickness of 125 μm by sputtering (production pressure: 0.1 Pa, production power: 180 W). A dry film resist (SUNFORT AQ-1558™, negative type, Asahi Kasei Corporation) was laminated on the entire surface of the Cr/Cu film under a laminating pressure of 0.4 kgf/cm² at a temperature of 120° C., and UV irradiation was performed through a photomask of a specific pattern, so that a desired pattern was transferred onto the dry film resist. Subsequently, the unexposed part of the resist was removed in an aqueous 0.5 wt % sodium carbonate solution, so that a resist image of a desired pattern was formed. The exposed part of the Cu film was etched with an etching solution (CA5330H manufactured by MEC CO., LTD.) at a temperature of 50° C. through the resist image used as a mask. The time required to etch the Cu film was 10 seconds. Subsequently, the resist was removed using a 2 wt % sodium hydroxide solution at a temperature of 50° C. Subsequently, the remaining part of the Cr film other than the Cu wiring part was removed using a selective etching solution (WCR3015™ manufactured by ADEKA CORPORATION) at a temperature of 40° C. so that a Cr/Cu metal mesh was formed, which had a hexagonal lattice mesh structure with an opening width of 0.45 mm and a line width of 0.05 mm. The metal mesh had an opening ratio of 82%.

An ITO film (thickness: 150 nm, sheet resistance: 20 Ω/square) as a transparent electrode was formed on the upper surface of the metal mesh by reactive ion plating (power: 3.7 kW, oxygen partial pressure: 73%, production pressure: 0.3 Pa, production rate: 150 nm/minute, substrate temperature: 20° C.) using a pressure gradient plasma gun. The ITO film-carrying substrate was then washed with acetone, a substrate cleaning solution, and IPA. This process reduced the apparent sheet resistance of the ITO electrode (the sheet resistance of a laminate of the ITO electrode and the metal mesh) to 0.1 Ω/square.

Subsequently, a film of an electrically-conductive polymer paste (Baytron™, manufactured by H.C. Starck GmbH.) was formed by spin coating on the ITO film-carrying substrate, and then dried at 150° C. for 30 minutes to form a hole extraction layer (thickness: 100 nm).

Subsequently, a photoelectric conversion layer was formed as in Example 1. The photoelectric conversion layer-carrying substrate was then exposed to the air.

Ca/Al (30 nm/200 nm in thickness) was then formed as a metal electrode on the photoelectric conversion layer by vacuum deposition.

The substrate having the photoelectric conversion layer and so on formed thereon was then dried by heating on a hot plate at a temperature of 150° C. Finally, sealing was performed with a sealing glass material and an adhesive sealing material from the top of the metal electrode, so that an organic thin-film solar cell was obtained.

The resulting organic thin-film solar cell was evaluated for current-voltage characteristics as in Example 1. The evaluation results are shown in Table 1.

TABLE 1

| | Opening | Short | Open | |
|---|---|---|---|---|
| | ratio (%) | circuit | circuit | Conversion |
| | Of | current | voltage | efficiency |
| | metal mesh | (mA/cm²) | (V) | (%) |
| Reference | 20 | 1.47 | 0.733 | 0.51 |
| Example 1 | | | | |
| Reference | 40 | 3.84 | 0.763 | 1.61 |
| Example 2 | | | | |
| Reference | 80 | 5.76 | 0.795 | 2.09 |
| Example 3 | | | | |

### Reference Examples 4 to 7

Organic thin-film solar cells were prepared as in Reference Examples 1 to 3, except that the respective thickness of the metal mesh was set as shown in Table 2 below, the opening ratio of the metal mesh was 80%, and the metal electrode Ca/Al was 30 nm/450 nm in thickness.

The resulting organic thin-film solar cells were evaluated for current-voltage characteristics as in Example 1. The evaluation results are shown in Table 2.

TABLE 2

| | | | Short | Open | |
|---|---|---|---|---|---|
| | Metal mesh | | circuit | circuit | Conversion |
| | thickness (nm) | | current | voltage | efficiency |
| | Cr | Cu | (mA/cm²) | (V) | (%) |
| Reference | 60 | 100 | 4.63 | 0.69 | 1.23 |
| Example 4 | | | | | |
| Reference | 60 | 1000 | 4.71 | 0.80 | 2.02 |
| Example 5 | | | | | |
| Reference | 60 | 2000 | 3.97 | 0.75 | 1.41 |
| Example 6 | | | | | |
| Reference | 60 | 3000 | 3.82 | 0.76 | 1.20 |
| Example 7 | | | | | |

The resulting conversion efficiency in Reference Example 5 with a Cu thickness of 1 μm was substantially equal to that in Reference Example 3 with a Cu thickness of 300 nm as shown above.

It was found that a too thick or thin metal mesh tended to reduce the conversion efficiency.

### Example 3

An ITO film (thickness: 150 nm, sheet resistance: 20 Ω/square) as a transparent electrode was formed on the upper surface of a PEN film substrate with an outside size of 50 mm square and a thickness of 125 μm by reactive ion plating (power: 3.7 kW, oxygen partial pressure: 73%, production pressure: 0.3 Pa, production rate: 150 nm/minute, substrate temperature: 20° C.) using a pressure gradient plasma gun. The ITO film-carrying substrate was then washed with acetone, a substrate cleaning solution, and IPA.

Subsequently, Ni/Cu/Ni each with the thicknesses shown in Table 3 below was laminated on the ITO film by sputtering (production pressure: 0.1 Pa, production power: 180 W). A dry film resist (SUNFORT AQ-1558™, negative type, Asahi Kasei Corporation) was laminated on the entire surface of the Ni/Cu/Ni film under a laminating pressure of 0.4 kgf/cm² at a temperature of 120° C., and UV irradiation was performed through a photomask of a specific pattern, so that a desired pattern was transferred onto the dry film resist. Subsequently, the unexposed part of the resist was removed in an aqueous 0.5 wt % sodium carbonate solution, so that a resist image of a desired pattern was formed. The exposed part of the Ni/Cu/Ni film was etched with an etching solution (CA5330H™ manufactured by MEC CO., LTD.) at a temperature of 50° C. through the resist image used as a mask. Subsequently, the resist was removed using a 2 wt % sodium hydroxide solution at a temperature of 50° C., so that an Ni/Cu/Ni metal mesh was formed, which had hexagonal openings arranged in a honeycomb pattern.

Subsequently, an electrically-conductive polymer paste (Baytron™, manufactured by H.C. Starck GmbH.) and a photoelectric conversion layer coating liquid (the same as in Example 1) were sequentially applied to the metal mesh using an automatic coater (Auto Film Applicator PI-1210™ manufactured by TESTER SANGYO CO., LTD.), so that a hole extraction layer and a photoelectric conversion layer were formed. In the process of forming the respective layers, the coating gap was set at 0.3 μm and 10 μm, respectively. The dry thickness of the hole extraction layer was 30 nm, and the dry thickness of the photoelectric conversion layer was 140 nm.

Finally, a Ca/Al electrode was formed on the photoelectric conversion layer by vapor deposition, so that a solar cell was obtained.

The solar cell characteristics were measured by the same method as in Example 1, and the results shown below were obtained.

TABLE 3

| | | | | | Short | Open | |
|---|---|---|---|---|---|---|---|
| | Metal mesh thickness | | | | circuit | circuit | Conversion |
| | (nm) | | | | current | voltage | efficiency |
| Example 3 | Ni | Cu | Ni | Total | (mA/cm²) | (V) | (%) |
| 3-1 | 20 | 160 | 20 | 200 | 5.72 | 0.77 | 2.05 |
| 3-2 | 20 | 260 | 20 | 300 | 5.84 | 0.78 | 2.12 |
| 3-3 | 20 | 360 | 20 | 400 | 4.82 | 0.64 | 1.28 |

| | | | | | |
|---|---|---|---|---|---|
| 3-4 | 20 | 960 | 20 | 1000 | Short |

It was demonstrated that when the thickness of the metal mesh exceeded 300 nm, the performance decreased and that when the thickness of the metal mesh was 1000 nm, a short circuit occurred.

### Example 4

Simulations were performed to optimize the mesh electrode shape. Mesh electrode models were constructed, in which various shapes of mesh electrodes were arranged, and an analysis was made of how the current flowed. The shape of the openings of the mesh electrode was set circular, triangular, tetragonal, or hexagonal, and their positions were changed with respect to the current direction, when the simulations were performed. The simulations were performed using Q3D Simulator manufactured by ANSYS Japan K.K.

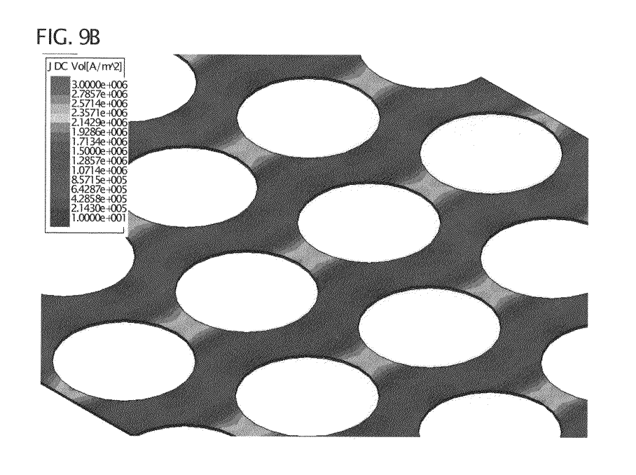

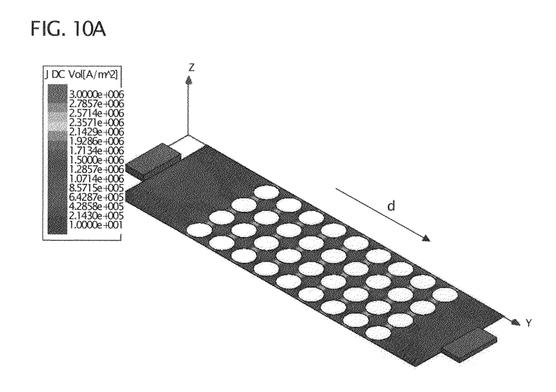

FIGS. 9 to 19 show the results of the simulation with each shape. In FIGS. 9 to 19, the arrow “d” indicates the current direction.

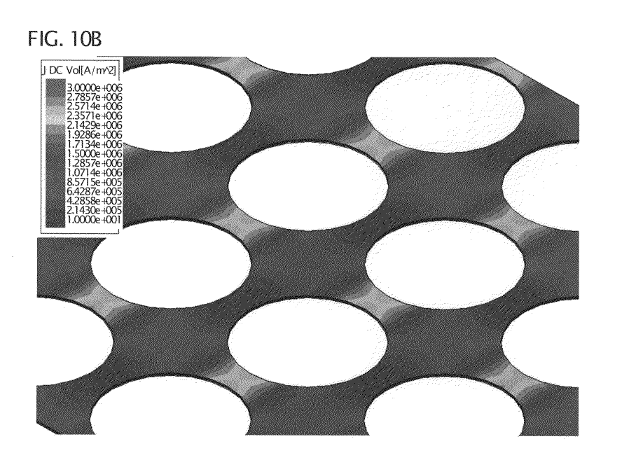

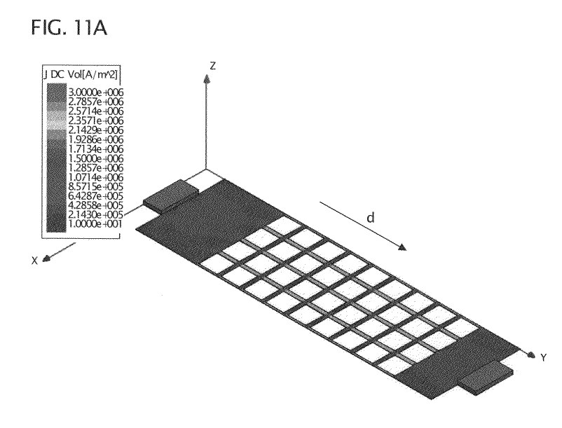

When the openings were circular, a low current region was formed ahead and behind the opening in both the case of a straight arrangement (FIGS. 10A and 10B) and the case of a zigzag arrangement (FIGS. 9A and 9B). It was found that circular openings gave rise to a loss of incident light.

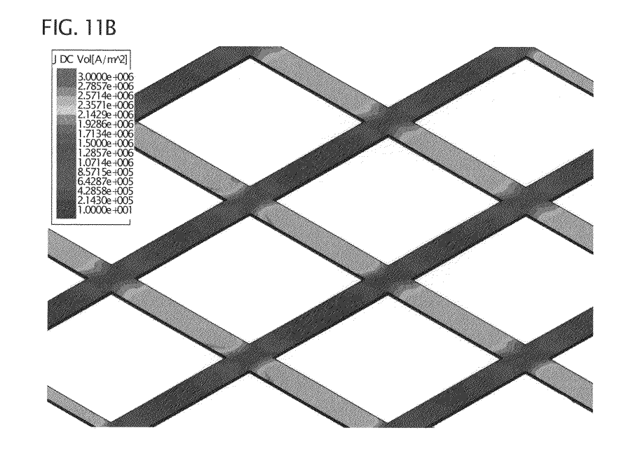

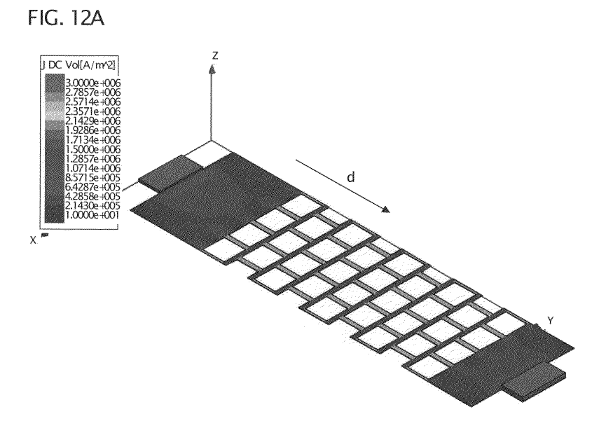

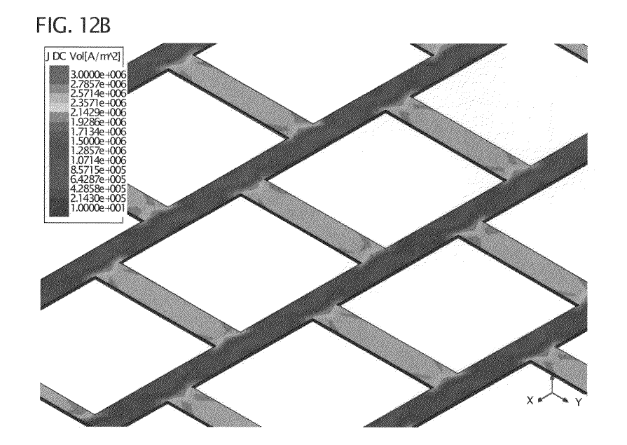

When the openings were tetragonal, the current did not transversely flow to the current direction in the case of a straight arrangement (FIGS. 11A and 11B). On the other hand, in the case of a zigzag arrangement (FIGS. 12A and 12B), a low current region was formed ahead and behind the opening, although the low current region significantly decreased.

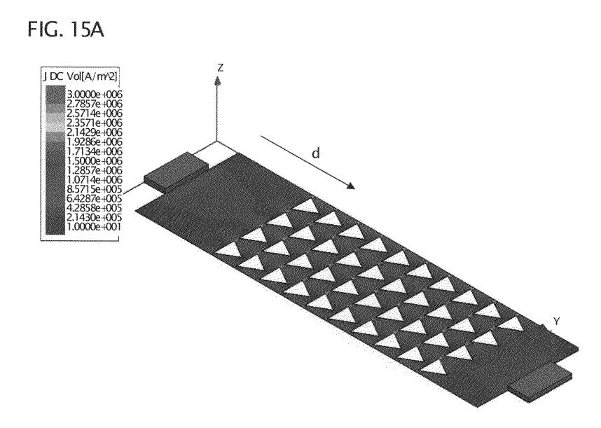

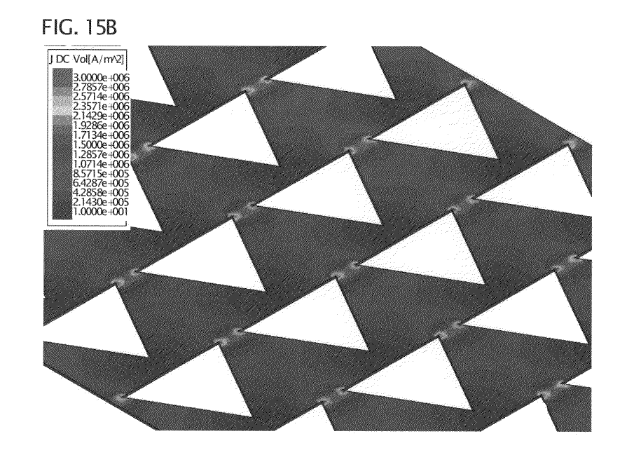

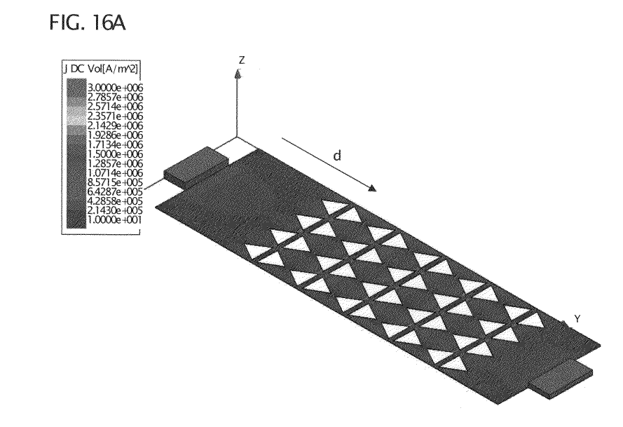

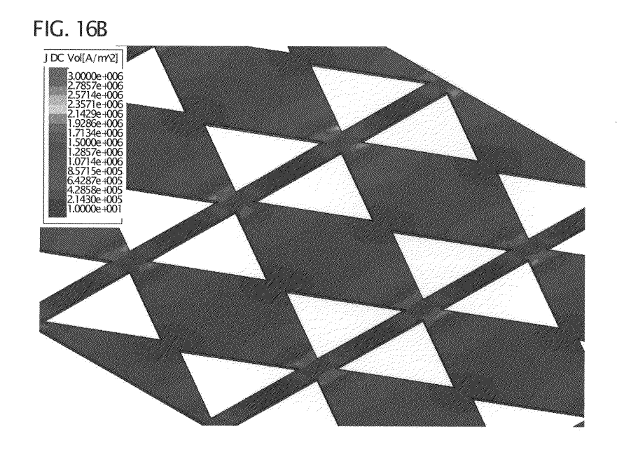

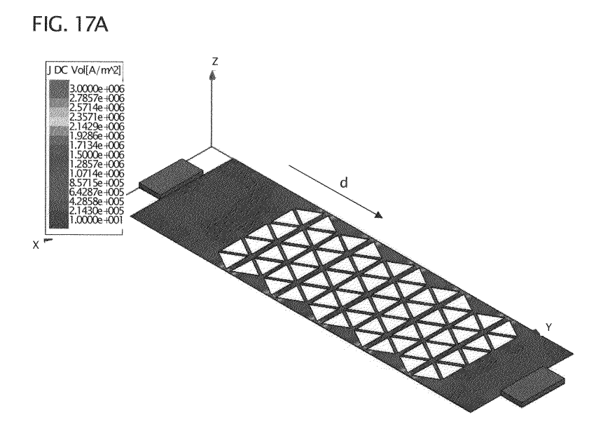

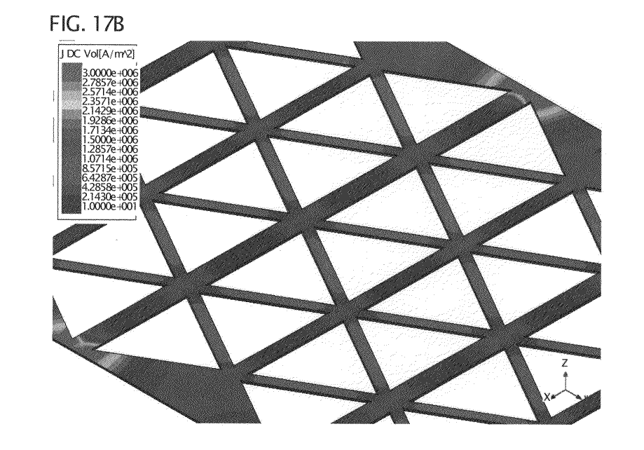

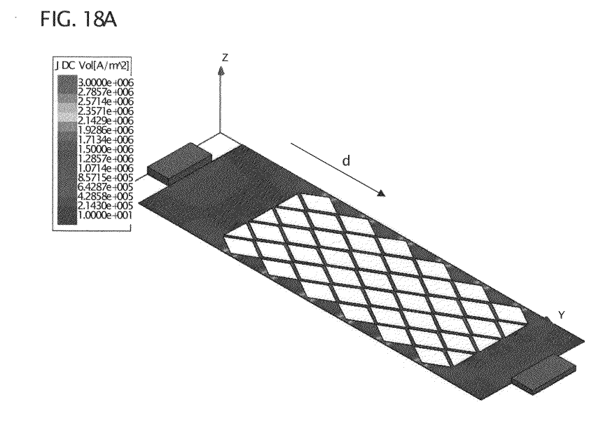

When the openings were triangular, an overcurrent region was formed at the edge of the opening in the case of a straight arrangement (FIGS. 15A and 15B and FIGS. 16A and 16B), and a low current region was formed ahead and behind the opening, so that the current density distribution became most uneven. On the other hand, in the case of a zigzag arrangement (FIGS. 17A and 17B), the current did not transversely flow to the current direction, so that a loss of incident light occurred, but a relatively uniform current distribution was found in the other region.

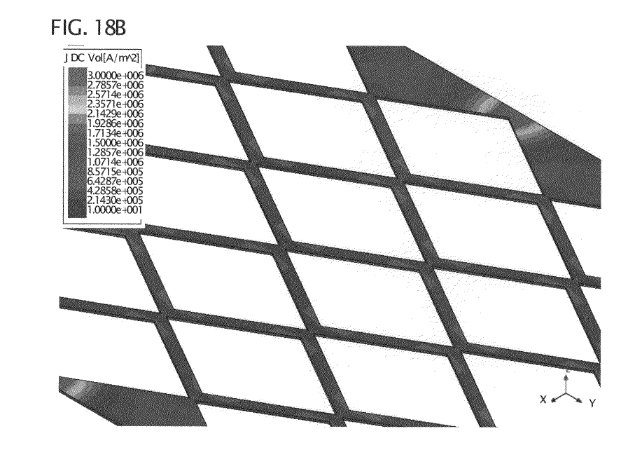

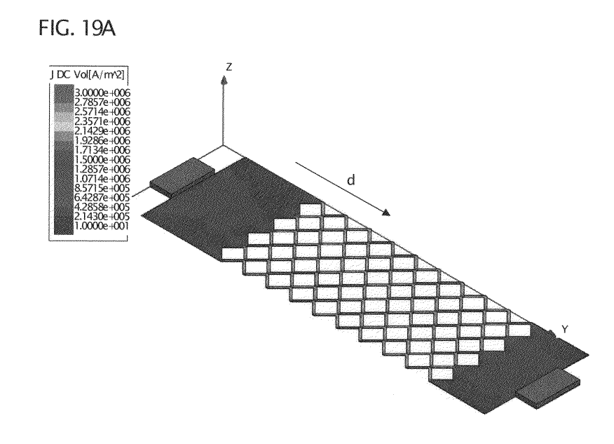

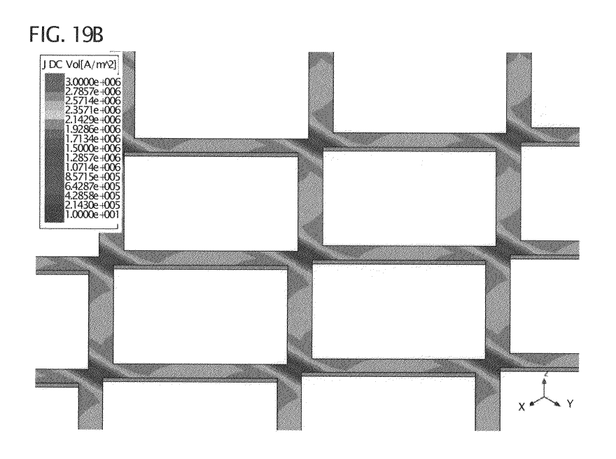

When the openings were in the shape of a rhombus with an acute angle of 60° (FIGS. 18A and 18B), an excellent current distribution was observed. On the other hand, when the angle was 90° (FIGS. 19A and 19B), a low current region was slightly formed at portions which the current direction crossed.

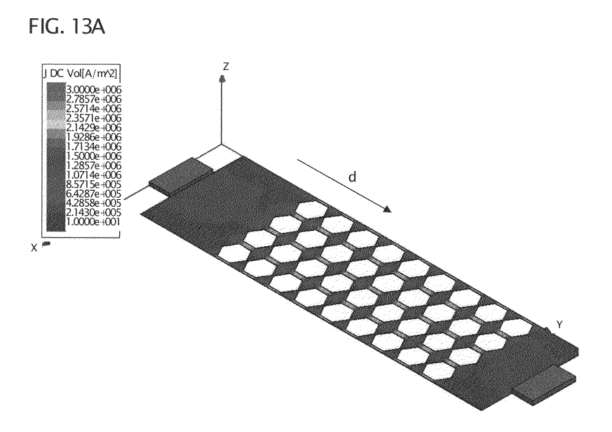

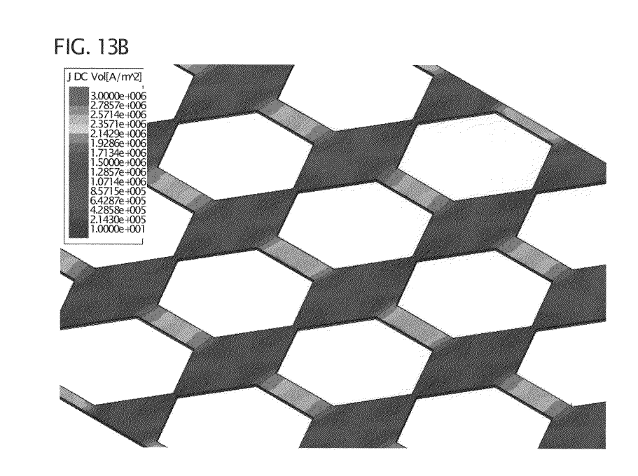

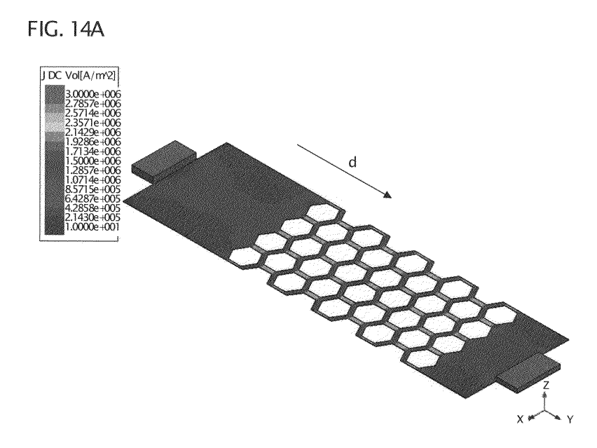

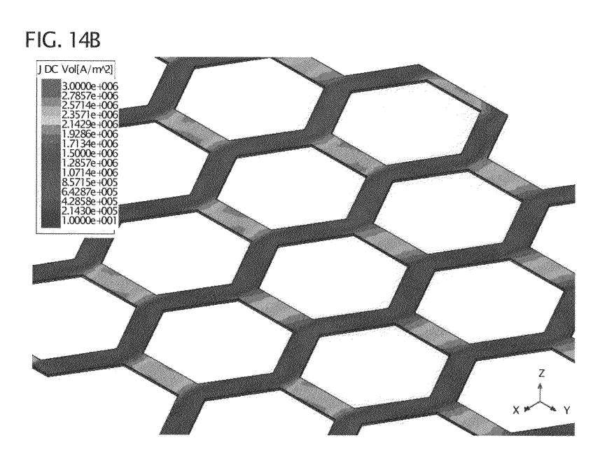

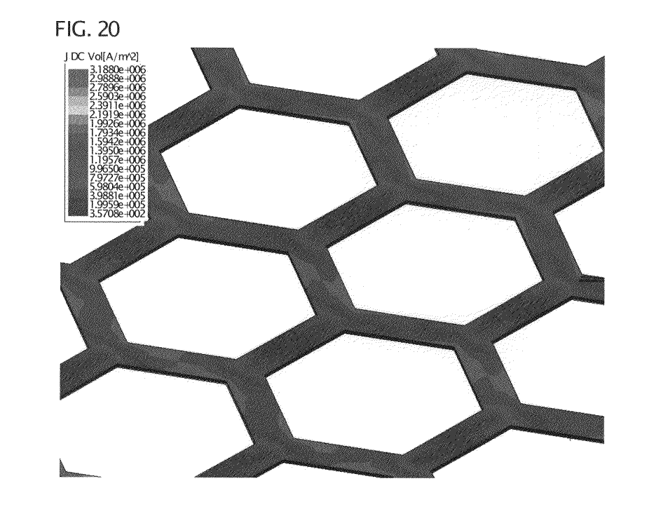

When the openings were hexagonal, a low current region occurred in the case of a straight arrangement (FIGS. 13A and 13B), and the current density distribution was not favorable. On the other hand, in the case of a zigzag arrangement (FIGS. 14A and 14B), a good current distribution was observed. In the case of a zigzag arrangement (FIG. 14B, FIG. 20), the rotation of the opening direction by 90° with respect to the current direction gave rise to the change of the overcurrent region and the low current region.

As a result, the hexagon and the rhombus provided a good current distribution.

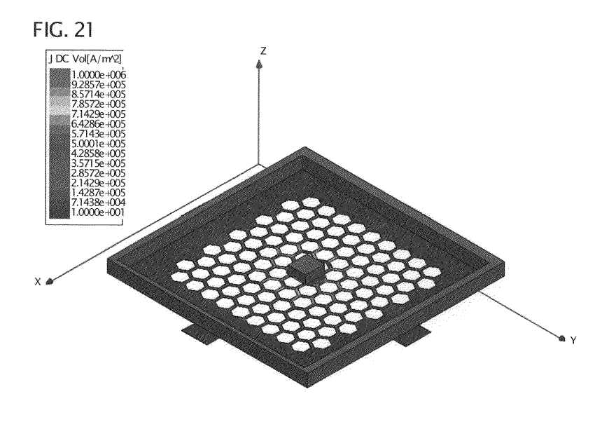

FIG. 21 shows the result of the simulation in the case where the current was allowed to flow radially from the center to the periphery when the openings were hexagonal. In this case, the current distribution was relatively uniform.

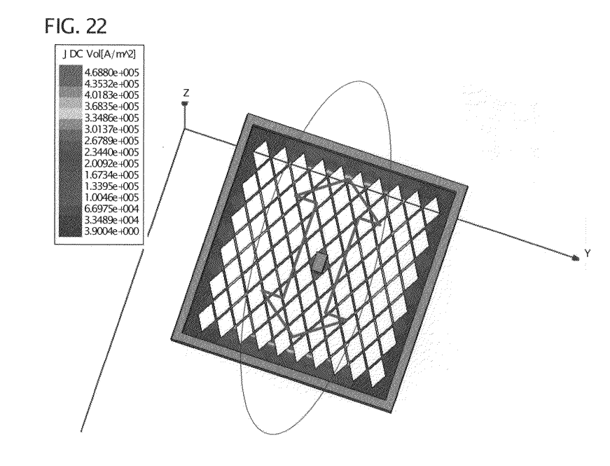

In addition, FIG. 22 shows the result of the simulation in the case where the current was allowed to flow radially from the center to the periphery when the openings were rhomboidal. In this case, the current distribution was also relatively uniform. The uniform-current area in which the current distribution was relatively uniform had an elliptical shape in which the current was more likely to flow in the direction of a diagonal between the acute corners of the rhombus.

### REFERENCE SIGNS LIST

1 organic thin-film solar cell

2 substrate

3 mesh electrode

4 transparent electrode

6 hole extraction layer

7 photoelectric conversion layer

8 counter electrode

9 electron extraction layer

11 incident light

1. An organic thin-film solar cell, comprising:
a transparent substrate;
a mesh electrode and a transparent electrode laminated in any order on the transparent substrate;
a photoelectric conversion layer formed on the mesh electrode and the transparent electrode; and
a counter electrode formed on the photoelectric conversion layer,
wherein the mesh electrode has such a thickness that no short circuit occurs between the counter electrode and the mesh electrode and the transparent electrode.

2. The organic thin-film solar cell according to claim 1, wherein the mesh electrode has the thickness in a range of 200 nm to 300 nm.

3. The organic thin-film solar cell according to claim 1, wherein the mesh electrode has a hexagonal or parallelogram lattice shape.

4. The organic thin-film solar cell according to claim 1, wherein the mesh electrode has an opening ratio in a range of 80% to 98%.

5. The organic thin-film solar cell according to claim 1, wherein the mesh electrode is a metal thin film formed by a vacuum film forming method.

6. The organic thin-film solar cell according to claim 1, wherein the mesh electrode and the transparent electrode are laminated in this order on the transparent substrate.

7. The organic thin-film solar cell according to claim 1, wherein the transparent electrode and the mesh electrode are laminated in this order on the transparent substrate.

8. A method for manufacturing an organic thin-film solar cell, in which the organic thin-film solar cell comprises: a transparent substrate, a mesh electrode and a transparent electrode laminated in any order on the transparent substrate, a photoelectric conversion layer formed on the mesh electrode and the transparent electrode, and a counter electrode formed on the photoelectric conversion layer, and
the method comprises: a mesh electrode-forming step of forming a metal thin film on the transparent substrate, placing a resist on the metal thin film, and patterning the metal thin film into a mesh structure by a photo-etching method to form the mesh electrode.

9. The method for manufacturing an organic thin-film solar cell according to claim 8, in which the mesh electrode has a thickness in a range of 200 nm to 300 nm, and the method further comprises after the mesh electrode-forming step: a photoelectric conversion layer-forming step of forming the photoelectric conversion layer by a method capable of controlling a thickness mainly depending on an amount of coating.

10. The method according to claim 8, wherein the metal thin film is patterned into a hexagonal or parallelogram lattice shape in the mesh electrode-forming step.
